(19) United States
(12) Patent Application Publication
(10) Pub. No.: US 2026/0283023 A1
(43) Pub. Date: Sep. 17, 2026

(54) INTEGRATED CIRCUIT PACKAGE WITH MEMORY DEVICE AND RECONSTRUCT FANOUT CONTROLLER

(71) Applicant: Micron Technology, Inc., Boise, ID (US)

(72) Inventors: Wen Wei Lum, Singapore (SG); Seng Kim Ye, Singapore (SG); Kelvin Tan Aik Boo, Singapore (SG); Hong Wan Ng, Singapore (SG)

(21) Appl. No.: 19/538,906

(22) Filed: Feb. 12, 2026

Related U.S. Application Data
(60) Provisional application No. 63/773,116, filed on Mar. 17, 2025.

(51) Int. Cl. H10W 90/00

(52) U.S. Cl. CPC H10W 90/00

(57) ABSTRACT

An integrated circuit includes a package substrate and a memory device disposed on the package substrate. The memory device includes a first stack comprising a plurality of first semiconductor dies, and a second stack comprising a plurality of second semiconductor dies. The integrated circuit also includes a fanout controller assembly that is mounted on the package substrate. The fanout controller assembly includes a controller substrate and a controller die disposed on the controller substrate. The controller die is encased in a mold, and a plurality of through-mold-vias (TMVs) are disposed adjacent the controller die. The TMVs extend from a top surface of the mold to the controller substate. A plurality of bondfingers are disposed on a top surface of the mold and electrically couple to respective TMVs.

### CROSS-REFERENCE TO RELATED APPLICATION(S)

The present application claims priority to U.S. Provisional Patent Application No. 63/773,116, filed Mar. 17, 2025, the disclosure of which is incorporated herein by reference in its entirety.

### TECHNICAL FIELD

The present disclosure generally relates to integrated circuits, and more particularly relates to integrated circuit assemblies including a memory device with multiple stacks of semiconductor dies and a controller die.

### BACKGROUND

Semiconductor devices, such as memory devices, are widely used to store information related to various electronic devices such as computers, wireless communication devices, cameras, digital displays, and the like. Memory devices are frequently provided as internal, semiconductor, integrated circuits and/or external removable devices in computers or other electronic devices. There are many different types of memory, including volatile and non-volatile memory. Volatile memory, including random-access memory (RAM), static random access memory (SRAM), dynamic random access memory (DRAM), and synchronous dynamic random access memory (SDRAM), among others, may require a source of applied power to maintain its data. Non-volatile memory, by contrast, can retain its stored data even when not externally powered. Non-volatile memory is available in a wide variety of technologies, including flash memory (e.g., NAND and NOR) phase change memory (PCM), ferroelectric random access memory (FeRAM), resistive random access memory (RRAM), and magnetic random access memory (MRAM), among others. Improving memory devices, generally, may include increasing memory cell density, increasing read/write speeds or otherwise reducing operational latency, increasing reliability, increasing data retention, reducing power consumption, or reducing manufacturing costs, among other metrics. In addition, to provide additional capacity, more than one semiconductor die can be included in each memory device package. Based on the manufacturer, a memory device package can have up 16 or 32 semiconductor dies. However, trends in the semiconductor industry indicate that memory device packages having more than 32 dies can be advantageous to integrated circuit designs. But there is also countervailing industry pressures to maintain the integrated circuit with the memory device package at approximately the same x-y form factor or smaller.

### BRIEF DESCRIPTION OF THE DRAWINGS

FIG. 1A is a block diagram of a side view of a related art integrated circuit package having a memory device package and a controller package.

FIG. 1B is a block diagram of a side cross-sectional view of the memory device package of FIG. 1A.

FIG. 1C is a block diagram of a top view of the memory device package of FIG. 1A.

FIG. 2 is a block diagram of side cross-sectional view of an embodiment of an integrated circuit with a memory device and a reconstruct fanout controller assembly in accordance with the present disclosure.

FIG. 3A is a partial block diagram of a top view of a sub-stack in the memory device package of FIG. 2.

FIG. 3B is a block diagram of a side cross-sectional view of a sub-stack of FIG. 3A on a package substrate.

FIG. 3C is a block diagram of a top view of the reconstruct fanout controller of FIG. 2.

FIG. 4 is a block diagram of side cross-sectional view of an embodiment of an integrated circuit with a memory device and a controller die in accordance with the present disclosure.

### DETAILED DESCRIPTION

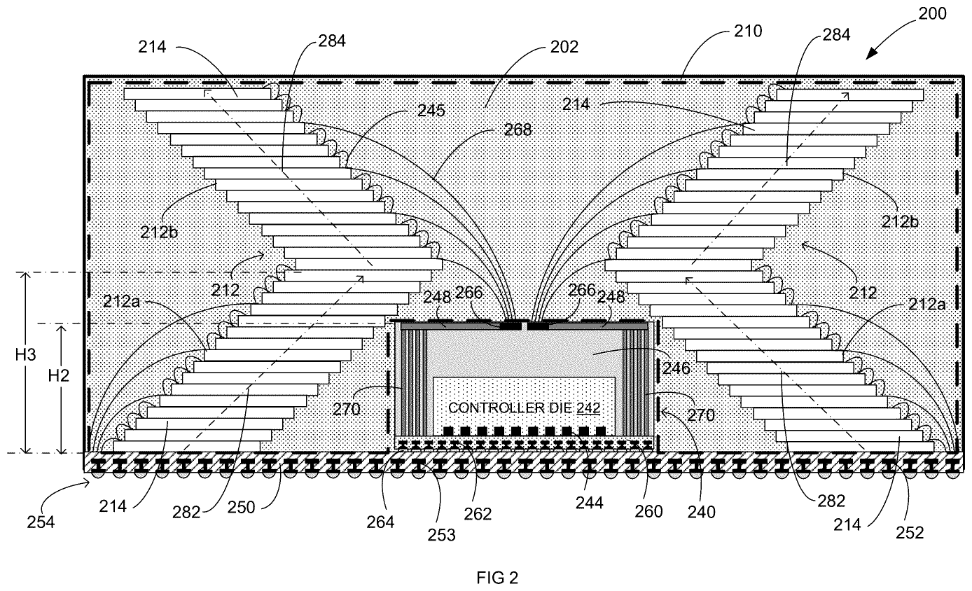

As discussed in greater detail below, the technology disclosed herein relates to memory devices, the packaging of semiconductor dies in a memory device, and an integrated circuit including the memory device and a controller. A person skilled in the art, however, will understand that the technology may have additional embodiments and that the technology may be practiced without several of the details of the embodiments described below with reference to FIGS. 2 to 4.

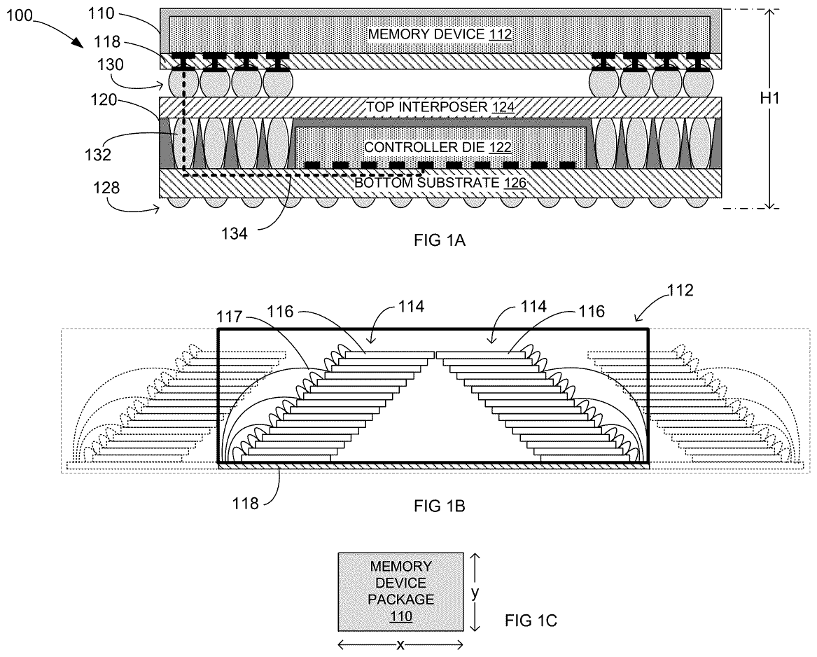

In related art integrated circuits, a memory device, with one or more semiconductor dies, can be independently packaged and then functionally connected to a controller package (e.g., a controller package containing a system-on-chip (SoC), an application-specific integrated circuit (ASIC), or another type of processing unit or controller) using a package-on-package (POP) assembly process to create an integrated circuit. For example, FIG. 1A illustrates a related art integrated circuit package 100 that is configured using a POP assembly process. The integrated circuit package 100 includes a memory die package 110, which includes a memory device 112, and a controller package 120, which includes a controller die 122. The memory device package 110 is disposed on the controller package 120 using POP technology. The memory device package 110 communicatively couples to the controller package 120 via a ball grid array (BGA) 130 disposed on memory substrate 118. The BGA 130 is electrically connected to pads or contacts (not shown) on top interposer 124 of controller package 120.

The top interposer 124 includes metal layers (not shown) that route signals from/to the memory device 112 and the controller die 122 and/or to other components. The top interposer 124 is communicatively coupled to the bottom substate via through-mold-vias (TMVs) 132 (or other connection means). The bottom substrate 126 includes metal layers (not shown) that route signals from/to the TMVs, the controller die 122, and/or to other components. A BGA 128 is disposed on the bottom substrate 126 for communication from/to the integrated circuit package 100 and external components. In the above integrated circuit package 100, because power and signals (e.g., see signal 134) from/to the controller die 122 and memory device 112 must go through multiple interconnections (e.g., interconnections corresponding to bottom substrate 126, TMVs 132, top interposer 124, BGA 130, and memory substrate 118), there can be significant power and/or signal loss, which can lead to electrical performance drop.

FIG. 1B illustrates a simplified cross-sectional view of the memory device package 110. The memory device package 110 includes the memory device 112 which can include stacks 114. Each stack 114 can include multiple semiconductor dies 116 (e.g., up to 16 semiconductor dies) mounted on the memory substrate 118. Each semiconductor die 116 can have a substrate and memory components (e.g., memory cell arrays, logic circuits, etc.) can be disposed in a layer on top of the respective substrate. As seen in FIG. 1B, the semiconductor dies 116 in each stack 114 are assembled in a shingled arrangement on the memory substrate 118. That is, for any two stacked semiconductor dies 116, the top semiconductor die is disposed on the bottom semiconductor die using an offset pattern similar to that of shingles on a roof. Each semiconductor die 116 is configured such that the respective bond pads (not shown) are exposed when the semiconductor dies 116 are stacked in the shingled arrangement, so that the exposed bond pads of each semiconductor die can be bonded (e.g., with a bond wire) to each other and/or to corresponding bondfingers on the memory substrate 118.

The memory device 112 can include up to 32 semiconductor dies 116. To increase the amount of memory in the memory device, additional semiconductor dies need to be added to the package. However, as seen in FIG. 1B, the top semiconductor dies 116 on each stack 114 are nearly touching. Thus, because the semiconductor dies 116 would interfere with each other, additional semiconductor dies 116 cannot merely be added to the top of each stack in the related art stacking process.

One solution can be to further separate the starting point of the stacks 114 (e.g., see placement of the stacks in dotted outline). However, by further separating the stacks, the die area (x-y form factor-see FIG. 1C) of the memory device package 110 will increase, which is not desirable when trying to maintain or decrease the size of the integrated circuit package 100. In addition, as new semiconductor dies 116 are added, the length of the bond wires 117 between the uppermost semiconductor dies and the package substrate 118 can get too long and lead to adverse issues with respect to electrical and/or physical design criteria (e.g., degradation in the functional signal speed degradation, reduced current carrying capacity, continuity breaks or flaws in the bond wires, and/or other adverse issues). Another solution can be to add additional stacks to the memory device. For example, the stacks in dotted outline can be additional stacks leading to a 4-stack configuration. However, if the number of stacks is increased, the die area of the memory die package 110 will need to increase, which is not desirable. In addition, the routing of the bond wires between the stacks can get congested, which can lead to bond wire routing difficulties and/or unreliable operation due to signal noise. In exemplary embodiments of the present disclosure, the die area can be kept approximately the same or less than related art memory devices by integrating the memory device package and controller package into a single package and maintaining the height of the integrated circuit to approximately the same as a POP assembly. For example, as seen in FIG. 1A, the integrated circuit package 100 has a height H1. By integrating the memory device package and controller package, additional semiconductor dies can be added to an integrated circuit package, while keeping the die area (x-y form factor) and/or the height of the integrated circuit to approximately that of related art POP integrated circuit packages.

Exemplary embodiments of the present technology are directed to memory devices having stacked semiconductor dies and to integrated circuits that include the memory devices. In some exemplary embodiments, an integrated circuit includes a package substrate and a memory device disposed on the package substrate. The memory device can include a first stack comprising a plurality of first semiconductor dies, and a second stack comprising a plurality of second semiconductor dies. The integrated circuit can include a fanout controller assembly that is mounted on the package substrate. In some embodiments, the fanout controller assembly can include a controller substrate and a controller die disposed on the controller substrate. The controller die can be encased in a mold, and a plurality of through-mold-vias (TMVs) can be disposed adjacent the controller die. In some embodiments, the TMVs can extend from a top surface of the mold to the controller substate and can conduct power and signal transmissions from a plurality of bondfingers that are disposed on a top surface of the mold and electrically coupled to respective TMVs. In some embodiments, the number of the semiconductor dies in the integrated circuit package can be greater than 32 semiconductor dies such as, for example, 64 semiconductor dies or 128 semiconductor dies. In some embodiments, each stack can have a bottom stack portion that is sloped toward the fanout controller assembly and a top stack portion that is sloped away from the fanout controller assembly. At least a portion of the integrated circuit can be assembled using a wafer level packaging process.

FIG. 2 is a cross-sectional view of an integrated circuit in accordance with an embodiment of the present disclosure. The integrated circuit package 200 includes memory device 210 (see dotted outline), a controller assembly 240, and a package substrate 250. In some embodiments, the controller assembly 240 can be a reconstruct fanout controller. For example, the controller die 242 can be reconstructed into a fanout controller to increase routing options for signals transmitted to/from the controller die 242 in comparison to a traditional controller die (e.g., fan-in controller). In some embodiments, the controller die can be reconstructed into a fanout controller independently and then installed in the integrated circuit package 200. In other embodiments, the controller die can be reconstructed into a fanout controller as part of the assembly of integrated circuit package 200. The controller assembly 240 can be mounted on the package substrate 250, which is comprised of several layers that include metal layers 253 for signal and power transmission and insulating layers to reduce noise related to the signal and power transmissions. In some embodiments, the controller die 242 can be a SoC, an ASIC, a graphics processing unit (GPU), computer processing unit (CPU), a tensor processing unit (TCU), and/or any other suitable processing unit. In some embodiments, some or all of the memory control functions for controlling memory device 210 can be incorporated into the controller die 242. In other embodiments, the memory device 210 can include a separate controller for performing the memory control functions.

In some embodiments, the controller assembly 240 (e.g., a reconstruct fanout controller) can include a controller die 242 that can be mounted onto a controller substrate 260 and encapsulated in a controller mold 246 (e.g., using a plastic such as, for example, epoxy, and/or another appropriate material). The controller mold 246 can extend to the controller substrate 260. The controller die 242 can include pins 244 (or another type of interconnection) to electrically couple the controller die 242 to the controller substrate 260. For example, the controller substrate 260 can have one or more metal layers 262, which electrically couple to the one or more pins 244 of the controller die 242 when assembled. In some embodiments, the controller substrate 260 can include a ball grid array 264 on the side away from the controller die 242 to connect to external components. For example, the BGA 264 can electrically couple to corresponding pads or contacts (not shown) in the package substrate 250.

In some embodiments, the controller assembly 240 can include one or more through-mold-vias (TMVs) 270 disposed adjacent to the controller die 242. Each TMVs 270 can extend through the controller mold 246 from the top surface of the controller mold 246 to the bottom surface of controller mold 246 at the interface with the controller substrate 260. The interior of each TMV 270 can be coated or deposited with an electrically conductive material such as, for example, copper or other appropriate metal. In some embodiments, the controller assembly 240 can include bondfingers 266 that are disposed on top of the controller mold 246 to interface with the memory device 210. In some embodiments, the controller assembly 240 can include trace lines 248 that are disposed on the top of the controller mold 246. The trace lines 248 electrically connect each TMV 270 to the corresponding bondfinger 266. The trace lines 248 can include an electrically conductive material such as, for example, copper or other appropriate metal. The other end of each TMV 270 electrically connect to, for example, one or more conductive layers 262 in the controller substrate 260. For clarity, individual connections between the TMVs 270 to the conductive layers 262 and between pins 244 to the conductive layers 262 are not shown in FIG. 2.

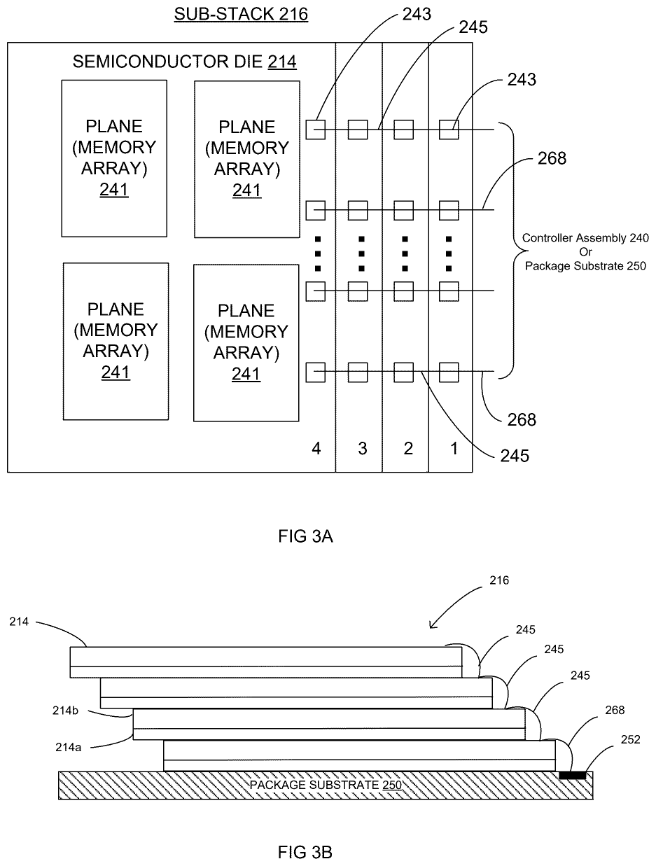

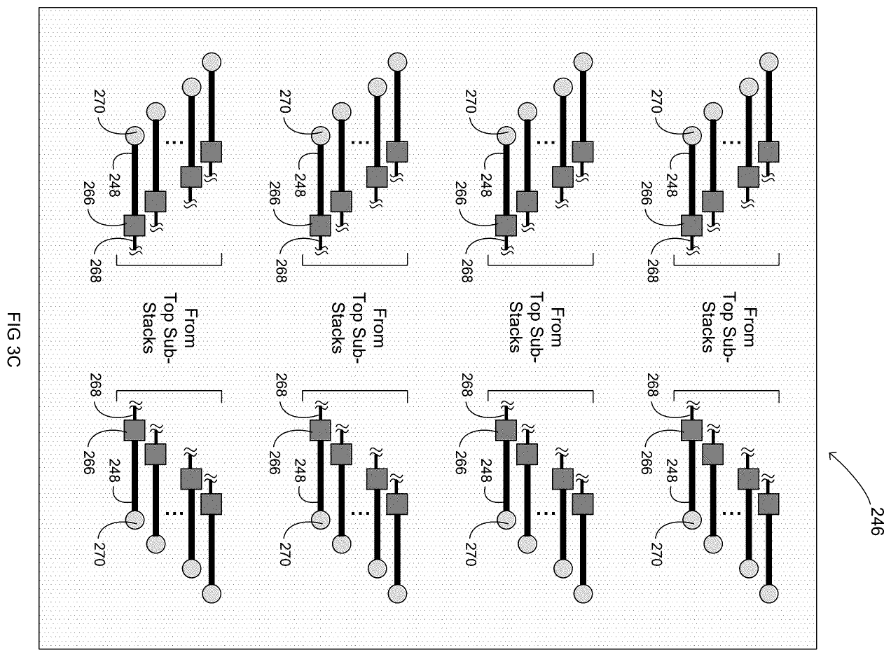

The memory device 210 includes multiple stacks 212 (e.g., two stacks) made up of semiconductor dies 214. Each semiconductor die 214 can have a die substrate 214a (see FIG. 3B) and a layer 214b on top of the die substrate 214a. Each semiconductor die 214 can include memory circuits (e.g., memory cell array, memory controllers, and/or associated logic) that can be disposed in layer 214b. For example, each semiconductor die can include active circuits (e.g., providing functional features such as memory cells, processor circuits, and/or imager devices) and/or passive circuits (e.g., capacitors, resistors, etc.) as well as contact pads (also referred to herein as “bond pads”) electrically connected to the circuits. As discussed below, the bond pads can be electrically connected to external terminals via corresponding bondfingers to allow the semiconductor die to be connected to each other and/or higher level circuitry.

In some embodiments, one or more of the stacks 212 can be segmented into one or more memory sub-stacks 216 (see FIGS. 3A and 3B) with each memory sub-stack 216 including one or more semiconductor dies 214. For example, a sub-stack 216 can include four semiconductor dies 214 stacked in a shingled arrangement. In other embodiments, the sub-stack 216 can include more than or less than four semiconductor dies. In some embodiments, the memory device 210 can have multiple sub-stacks 216 that are stacked on top of each other. One or more stacks 212 of the memory device 210 can include more than 16 semiconductor dies 214. In some embodiments, each stack 212 includes 32 semiconductor dies 214 for a total of 64 semiconductor dies 214 in the integrated circuit package 200. However, in other embodiments, the number of semiconductor dies 214 in memory device 210 can be greater than 64 (e.g., 128) or less than 64. In the exemplary embodiment of FIG. 2, the semiconductor dies 214 of each stack 212 are grouped into eight sub-stacks 216 with each sub-stack 216 including four semiconductor dies 214. In other embodiments, however, the number of sub-stack groupings per stack and the number of semiconductor dies per sub-stack can be different. In addition, in some embodiments, the stacks need not have the same number of semiconductor dies. In some embodiments, each stack 212 includes a bottom stack portion 212a and a top stack portion 212b. As seen in FIG. 2, the number of sub-stacks and/or semiconductor dies in bottom stack portion 212a is the same as those in the top stack portion 212b. However, in other embodiments, the bottom stack portion 212a and the top stack portion 212b can have different number of sub-stacks and/or semiconductor dies.

In some embodiments, the slope direction of the semiconductor dies can be different between the bottom stack portion 212a and the top stack portion 212b. “Slope direction” as used herein refers to the direction of a line extending away from the package substrate and through the centers of the semiconductor dies from the bottom semiconductor die of the stack portion to the top semiconductor die of the stack portion. However, in other embodiment, the slope direction can be the same between the top and bottom stack portions of the stack 212. In the embodiment of FIG. 2, the slope direction 282 (see dotted arrows) of the bottom stack portion 212a of each stack 212 is toward the controller assembly 240 (e.g., toward the center of the integrated circuit package 200), and the slope direction 284 (see dotted arrows) of the top stack portion 212b of each stack 212 is away from the controller assembly 240 (e.g., toward the side ends of the integrated circuit package 200). In the embodiments of FIG. 2, the pattern on the slope directions between the bottom stack potions 212a and the respective top stack portions 212b resembles a wing-shaped structure on each stack 212. The wing-shaped stack structure allows for the location of the bond pads on the top stack portion 212b to be opposite that of the bond pads on the bottom stack portion 212a. For example, the bond pads on each semiconductor die 214 of the bottom stack portion 212a are located away from the controller assembly 240, and the bond pads on each semiconductor die 214 of the top stack portion 212b are located toward the controller assembly 240. In some embodiments, the semiconductor dies are all configured the same and the semiconductor dies on the top stack portion 212b are rotated 180 degrees from those in the bottom stack portion 212a. In other embodiments, the semiconductor dies from the top stack portion 212b are configured differently from those in the bottom stack portion such that the location of the bond pads are opposite those in bottom stack portion 212a.

FIG. 3A illustrates a simplified block diagram of a sub-stack 216 that is consistent with the present disclosure. Each semiconductor die 214 can include one or more planes 241 incorporating one or more memory cell arrays (not shown) and one or more bond pads 243. For clarity, only four bond pads 243 are illustrated for each semiconductor die (and only some components are labeled). The actual number of bond pads, however, can depend on the type of memory device. The bond pads 243 can facilitate communicative couplings between each semiconductor die 214 and other semiconductor dies 214, controller assembly 240, and/or the package substrate 250. For example, bond wires 268, can electrically couple the semiconductor die 214 to the controller assembly 240 or the package substrate 250 by attaching the bond pads 243 on the semiconductor die 214 to bondfingers 266 on the controller assembly 240 or to bondfingers 252 on the package substrate 250. In the illustrated embodiment, the bond wires 268 electrically connect one semiconductor die 214 in the sub-stack 216 to bondfingers 266 or bondfingers 252. The other semiconductor dies 214 in each sub-stack 216 can be serially connected to one another in a daisy chain through the bond wires 245 (see also FIG. 3B), thereby providing an electrical connection between each semiconductor die 214 to the controller assembly 240 or to the package substrate 250. Alternatively, or in addition to bond pads, vias may be employed to couple some or all semiconductor dies 214 in the sub-stack 216. In some embodiments, instead of a daisy chain, bond wires 268 can directly couple each of the semiconductor dies 214 to the controller assembly 240 or to the package substrate 250. In some embodiments, instead of wires, other conductive materials such as, for example, conductive ribbons or strips, can be used to provide the electrical couplings. Those skilled in the art understand the memory cell array configuration in a semiconductor die, including the routing of connections to the bond pads. Thus, for brevity, the routing and connection details are not discussed except as necessary to understand the present technology.

FIG. 3B illustrates a cross-sectional view of a sub-stack 216 that is disposed on the package substrate 250 (e.g., the bottom sub-stacks in the bottom stack portions 212a). The package substrate 250 can include bondfingers 252 that can act as a termination point for bond wires 268 from the sub-stacks 216. FIG. 3C illustrates a top view of the controller assembly 240. As seen in FIG. 3C, the bond wires 268 from each sub-stack 216 in the top stack portion 212b of stacks 212 can be terminated on corresponding bondfingers 266 disposed on top of the controller mold 246. Each bondfinger 266 is electrically connected to a corresponding TMV 270 via a trace line 248.

In the above embodiment, the stacks 212 have a wing-shaped structure due the slope directions being different between the bottom stack portion 212a and the top stack portion 212b, and the controller assembly 240 is a reconstruct fanout controller. This configuration facilitates the routing of bond wires 268 from the bond pads 243 of top stack portions 212b to the bondfingers 266 on top of the controller assembly 240, which can be disposed between the two stacks 212. Because the top of the controller assembly 240 is above the top surface of the package substrate 250 by a height H2, the bond wires 268 are shorter than if they were routed to the bondfingers 252 of the package substrate 250. By routing the bond wires 268 of the top stack portions 212b to the controller assembly 240 instead of the package substrate 250, in some embodiments, the lengths of all the bond wires 268 can be kept short enough to avoid or minimize the adverse characteristics related to long bond wire lengths (e.g., degradation in the functional signal speed degradation, reduced current carrying capacity, continuity breaks or flaws in the bond wires, and/or other adverse characteristics). In some embodiments, the height H2 is less than or equal to the height H3 of the bottom stack portion 212a from the package substrate 250.

The package substrate 250 can include pads or contacts and/or metal layers to route signals and/or power from/to the memory device 210, the controller assembly 240, and/or other internal components. In some embodiments, a BGA 254 can be disposed on the bottom of the package substrate 250 to communicate signals and/or power from/to external devices. The package substrate 250 can include conductive layers 253 to route signals from/to the controller substrate 260 (e.g., signals related to the top stack portions 212b, controller die 242, etc.), the bondfingers 252 for the bottom stack portion 212a, other components internal to integrated circuit package 200, and/or components external to the integrated circuit package 200. In the above embodiments, the controller assembly 240 can be a reconstructed fanout controller, which provides additional routing options (e.g., due to the TMVs 270 and/or controller substrate 260) for signal and/or power between controller die 242 and memory device 210 (and/or other components both internal and external). The additional routing options allow for efficient signal and power routing. Typically, a package substrate includes metal layers and insulating layers to minimize the noise due to the signal/power routings. The number of substrate layers in traditional memory devices can be 6 or more. However, because of signal and power efficiency due to increased routings option of the fanout controller, the number of layers in package substrate 250 can be less than 6 such as, for example, 4 layers.

In some embodiments, at least a portion of the integrated circuit package 200 with the reconstruct fanout controller can be manufactured using wafer level packaging (WLP). WLP is known in the art and thus, for brevity, will not be discussed in detail except as needed to describe the exemplary embodiments. In some embodiments, the controller substrate 260 (which includes, for exmaple, the metal layers, contact pads for the controller pins 244, and BGA 264 for interfacing with the package substrate 250) can be disposed on the package substrate 250 (which can include, for emxaple, the appropriate metal layers, contact pads, and bondfingers 252). A controller die 242 can be electrically coupled to the controller substrate 260 via the controller pins 244. The controller die 242 can be encased in the controller mold 246 and TMVs 270 can be formed in the controller mold 246. The fanout section including bondfingers 266 and trace lines 248 can be formed on top of the controller mold 246 (e.g., a redistribution and metallization layer) to complete reconstruction of the controller die 242 into a fanout controller (e.g., controller assembly 240). In some embodiments, a pre-configured reconstructed fanout controller can be assembled separately and then disposed on the package substrate 250.

After (or during) the construction of controller assembly 240, the bottom stack portions 212a can be stacked using a shingled arrangement on either side of the controller assembly 240 with a respective slope direction 282 (see dotted arrows) that is towards the controller assembly 240. After (or during) the stacking of the bottom stack portions 212a, bond wires 245 can be formed between semiconductor dies 214 of a sub-stack 216 and/or bond wires 268 can be formed between one or more semiconductor dies 214 of a sub-stack 216 and bondfingers 252 on the package substrate 250, as discussed above. After the bottom stack portions 212a have been formed, the top stack portions 212b can be stacked on the respective bottom stack portions 212a using a shingled arrangement with a respective slope direction 284 (see dotted arrows) that is away from the controller assembly 240. After (or during) the stacking of the top stack portions 212b, bond wires 245 can be formed between semiconductor dies 214 of a sub-stack 216 and/or bond wires 268 can be formed between one or more semiconductor dies 214 of a sub-stack 216 and bondfingers 266 on the controller assembly 240, as discussed above. Once all the components and wiring have been formed, the package mold 202 can encapsulate the integrated circuit (e.g., using a plastic such as, for example, epoxy, and/or another appropriate material).

In the above embodiments, because integrated circuit package 200 includes both the memory device 210 and the controller die 242, the height H1 of the integrated circuit package 200 can be approximately the same as related art integrated circuit assembled using a POP process. In addition, because the wing-shaped stacks in the memory device 210, along with the controller assembly 240, allow for a more compact semiconductor die arrangement, the die area (x-y form factor) of a memory device with 64 semiconductor dies (or more) can be approximately the same as that of a related art memory die having only 16 semiconductor dies. In addition, the above embodiments resolve the adverse issues associated with long bond wires by including a fanout controller that keeps the length of the bond wires approximately the same as related art memory devices. Also, the above embodiments improve signal integrity and increase power delivery performance because the integrated package with the memory device and controller die reduces the number of interconnects in the integrated circuit and because the fanout controller allows for more routing options. The improved signal and power efficiency means that the package layer count can be reduced (e.g., less than 6 layers).

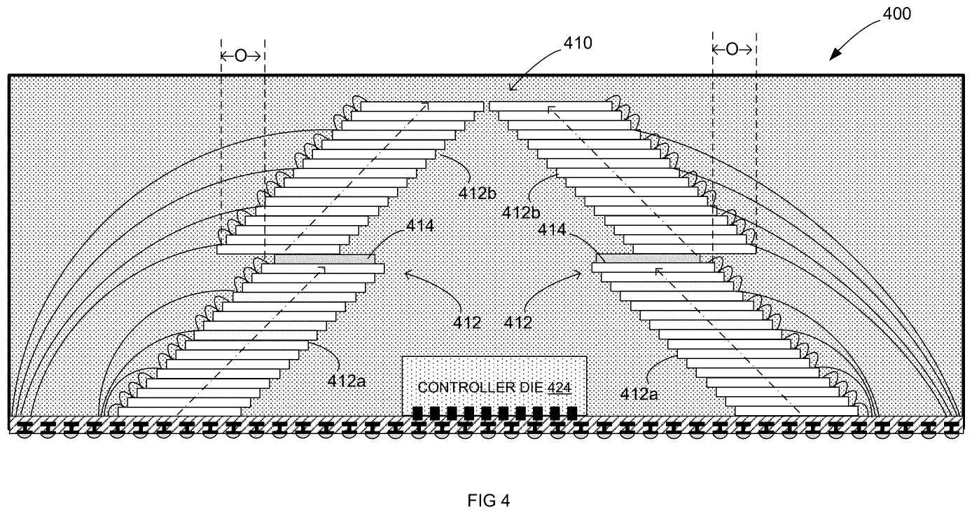

FIG. 4 illustrates another embodiment of an integrated circuit package consistent with the present disclosure. The integrated circuit package 400 includes a memory device 410 and a controller die 424. For brevity, only pertinent differences between the embodiments of FIG. 4 and the above embodiments are discussed. The memory device 410 can include stacks 412 disposed on opposite sides of a controller die 424. Each stack 412 can include a bottom stack portion 412a and a top stack portion 412b. Unlike the above embodiments, in the embodiment of FIG. 4, both the top stack portions 412b and the bottom stack portions 412a have a slope direction that is toward the controller die 424 (see dotted arrows). The controller die 424 can be disposed between the stacks 412. In some embodiments, the top stack portions 412b are offset from the respective bottom stack portions 412a by an offset O in a direction away from the controller die 424. A spacer layer 414 can be used in some embodiments to protect the bond wires on the topmost semiconductor die of the bottom stack portions 412a. The offset O allows for stacks 412 to be placed closer to the controller die 424 (and thus minimize the x-y form factor) without interference between the top semiconductor dies of the respective stacks. The offset O should be selected to minimize the die area (x-y form factor) without overstressing the bottommost semiconductor die of the respective top stack portions 412b.

Although the present invention has been described with reference to the disclosed embodiments, persons skilled in the art will recognize that changes may be made in form and detail without departing from the invention. For example, embodiments of the present disclosure are not limited to the stacking arrangements shown above so long as the memory device and controller die are integrated in an integrated circuit with the memory device having at least 64 semiconductor dies. Such modifications are well within the skill of those ordinarily skilled in the art. Accordingly, the invention is not limited except as by the appended claims.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

From the foregoing, it will be appreciated that specific embodiments of the technology have been described herein for purposes of illustration, but well-known structures and functions have not been shown or described in detail to avoid unnecessarily obscuring the description of the embodiments of the technology. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the terms “comprising,” “including,” “having,” and “with” are used throughout to mean including at least the recited feature(s) such that any greater number of the same feature and/or additional types of other features are not precluded.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those of ordinary skill in the relevant art will recognize. It will also be appreciated that various modifications may be made without deviating from the disclosure. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described.

I/We claim:

1. An integrated circuit, comprising:
a package substrate;
a memory device disposed on the package substrate, the memory device including,
a first stack comprising a plurality of first semiconductor dies, and
a second stack comprising a plurality of second semiconductor dies; and
a fanout controller assembly mounted on the package substrate and disposed between the first stack and the second stack, the controller assembly including,
a controller substrate,
a controller die disposed on the controller substrate and encased in a mold,
a plurality of through-mold-vias (TMVs) disposed adjacent the controller die and extending from a top surface of the mold to the controller substrate, and
a plurality of bondfingers disposed on a top surface of the mold, the bondfingers electrically coupled to respective TMVs of the plurality of TMVs.

2. The integrated circuit of claim 1, wherein a number of the first semiconductor dies and the second semiconductor dies is greater than 32 semiconductor dies.

3. The integrated circuit of claim 2, wherein the number is 64 semiconductor dies.

4. The integrated circuit of claim 2, wherein the number is 128 semiconductor dies.

5. The integrated circuit of claim 1, wherein each of the first and second stacks includes a top stack portion and a bottom stack portion,
wherein semiconductor dies in the top stack portion and the bottom stack portion are stacked in a shingled arrangement,
wherein a first slope direction of the shingled semiconductor dies in the bottom stack portions is toward the fanout controller assembly, and
wherein a second slope direction of the shingled semiconductor dies in the top stack portions is away from the fanout controller assembly.

6. The integrated circuit of claim 5, wherein first bond wires from semiconductor dies of the bottom stack portions are routed to bondfingers disposed on the package substrate, and
wherein second bond wires from semiconductor dies of the top stack portions are routed to the bondfingers disposed on the top surface of the mold.

7. The integrated circuit of claim 1, wherein a number of layers in the package substrate is less than 6.

8. The integrated circuit of claim 7, wherein the number of layers in the package substrate is 4.

9. The integrated circuit of claim 1, wherein at least a portion of the integrated circuit is assembled using wafer level packaging.

10. The integrated circuit of claim 1, wherein the controller die comprises one of a system-on-chip, an application-specific integrated circuit, or a memory controller.

11. An integrated circuit, comprising:
a package substrate;
a memory device, the memory device including,
a first stack of semiconductor dies disposed on the package substrate and set in a first slope direction,
a second stack of semiconductor dies disposed on the first stack and set in a second slope direction;
a third stack of semiconductor dies disposed on the package substrate and set in the first slope direction, and
a fourth stack of semiconductor dies disposed on the third stack and set in the second slope direction;
a controller unit mounted on the package substrate and disposed between the first stack and the second stack,
wherein a sum of semiconductor dies in the first, second, third, and fourth stacks is greater than 32 semiconductor dies.

12. The integrated circuit of claim 11, wherein the semiconductor dies of the first, second, third, and fourth stacks are set in a shingled arrangement, and
wherein the first slope direction is toward the controller unit, and the second slope direction is away from the controller unit.

13. The integrated circuit of claim 12, wherein the controller unit is a fanout controller assembly, the fanout controller assembly including,
a controller substrate,
a controller die disposed on the controller substrate and encased in a mold,
a plurality of through-mold-vias (TMVs) disposed adjacent the controller die and extending from a top surface of the mold to the controller substrate, and
a plurality of bondfingers disposed on a top surface of the mold, the bondfingers electrically coupled to respective TMVs of the plurality of TMVs.

14. The integrated circuit of claim 13, wherein first bond wires from semiconductor dies of the first and third stacks are routed to bondfingers disposed on the package substrate, and
wherein second bond wires from semiconductor dies of the second and fourth stacks are routed to the bondfingers disposed on the top surface of the mold.

15. The integrated circuit of claim 11, wherein the sum is 64 semiconductor dies.

16. The integrated circuit of claim 11, wherein the controller unit comprises one of a system-on-chip, an application-specific integrated circuit, or a memory controller.

17. The integrated circuit of claim 11, wherein a number of layers in the package substrate is less than 6.

18. The integrated circuit of claim 11, wherein at least a portion of the integrated circuit is assembled using wafer level packaging.

19. The integrated circuit of claim 11, wherein the controller unit is a controller die,
wherein the semiconductor dies of the first, second, third, and fourth stacks are set in a shingled arrangement, and
wherein the first and second slope directions are toward the controller die.

20. The integrated circuit of claim 19, wherein the second stack is offset from the first stack, and the fourth stack is offset from the third stack, and
wherein the offset is in a direction away form the controller die.
